(19) United States
(12) Patent Application Publication
(10) Pub. No.: US 2006/0071306 A1
(43) Pub. Date: Apr. 6, 2006

(54) Active device bases, leadframes utilizing the same, and leadframe fabrication methods

(75) Inventor: Chien-Chen Lee, Zhubei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Airoha Technology Corp.

(21) Appl. No.: 11/023,749

(22) Filed: Dec. 28, 2004

(30) Foreign Application Priority Data
Oct. 6, 2004 (TW) 93130206

(51) Int. Cl. H01L 23/495

(52) U.S. Cl. 257/666

(57) ABSTRACT

Active device bases, leadframes utilizing the same, and leadframe fabrication methods. The base includes a plate, a predetermined attachment area for an active device on a surface of the plate, and a recess in the predetermined attachment area, which substantially does not penetrate the plate.

### BACKGROUND

The invention relates to package technology and in particular to active device bases, leadframes utilizing the same, and leadframe fabrication methods.

FIG. 1A is a cross-section of a conventional package utilizing a leadframe having an active device base 10 and terminals 20 served as a package substrate. Wires 32 electrically connect the terminals and a chip 30 attached to the active device base 10. The chip 30 and wires 40 are encapsulated by an encapsulant 40.

FIG. 1B is a perspective cross-section of region A in FIG. 1A. The chip 30 is mounted on the active device base 10 by a glue layer 12 therebetween. Thermal stress induced by reliability tests standardized by Joint Electronic Engineering Council (JDEC) typically damage the interface between the chip 30 and active device base 10, resulting in nucleation and growth of cracks 13 between the glue layer 12 and active device base 10, thereby rejecting the conventional package.

Environmental concerns have lead countries or economies to increasingly request processes not utilizing lead. The soldering temperature of unleaded solders are at least 40° C. higher than that of tin-lead eutectic solder, resulting in critical requests for reliable green electronic products. Thus, development of a more reliable package utilizing a leadframe is desirable.

### SUMMARY

Active device bases, leadframes utilizing the same, and leadframe fabrication methods are provided.

An embodiment of an active device base comprises a plate; an active device overlying the base; a predetermined attachment area for an active device on a surface of the plate; and a recess in the predetermined attachment area. The recess substantially does not penetrate the plate.

An embodiment of a leadframe comprises: a plate; a predetermined attachment area for an active device on a surface of the plate; a recess in the predetermined attachment area; a plurality of terminals beyond the plate; and a peripheral boundary surrounding the terminals and the plate. The recess substantially does not penetrate the plate. The peripheral boundary is connected to the respective plate and the terminals.

An embodiment of a leadframe fabrication method comprises providing a semi-finished leadframe. The semi-finished leadframe comprises a plate, a plurality of terminals beyond the plate, and a peripheral boundary surrounding the terminals and the plate. The peripheral boundary is connected to the respective plate and the terminals. A patterned mask layer is then formed overlying the plate, exposing parts of the plate. Further, the exposed plate is etched to form a recess. The recess substantially does not penetrate the plate. Finally, the patterned mask layer is removed.

### DESCRIPTION OF THE DRAWINGS

The invention can be more fully understood by reading the subsequent detailed description in conjunction with the examples and references made to the accompanying drawings, wherein:

FIG. 1A is a cross-section of a conventional package.

FIG. 1B is a partial perspective cross-section of FIG. 1A.

FIG. 2A is a top view of an active device base of a first embodiment of the invention.

FIG. 2B is a cross-section along line BB in FIG. 2A.

FIG. 3A is a top view of an active device base of a variation of the first embodiment of the invention.

FIG. 3B is a cross-section along line CC in FIG. 3A.

FIG. 4 is a top view of an active device base of another variation of the first embodiment of the invention.

FIG. 5 is a top view of an active device base of another variation of the first embodiment of the invention.

FIG. 6 is a top view of a leadframe of a second embodiment of the invention.

FIGS. 7A through 7D are cross-sections of a leadframe fabrication method of a third embodiment of the invention.

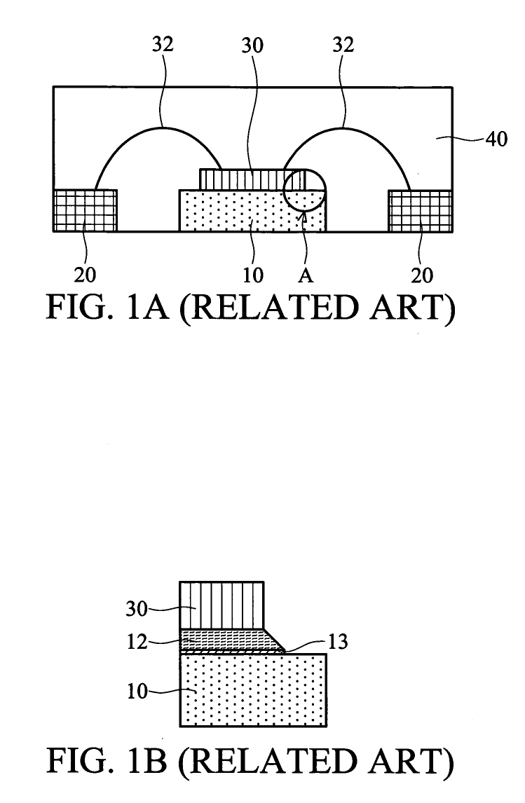

### DETAILED DESCRIPTION

Active device bases, leadframes utilizing the same, and leadframe fabrication methods are provided goes here. Active device bases, leadframes utilizing the same, and leadframe fabrication methods will be described in greater detail in the following.

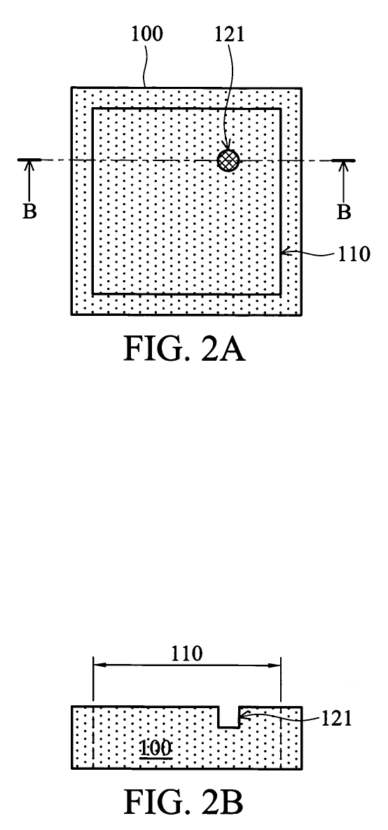

FIG. 2A is a top view of an active device base of a first embodiment of the invention. FIG. 2B is a cross-section along line BB in FIG. 2A.

Referring to FIG. 2A, the active base comprises a plate 100, preferably of a conductive material, to act as a grounding element for an active device (not shown) predetermined for attachment thereto. The plate 100 is more preferable metal when utilized by a leadframe. The plate 100 comprises a predetermined attachment area 100 for the active device. The plate 100 comprises a recess 121 in the predetermined attachment area 100. The recess 121 substantially does not penetrate the plate 100. The recess 121 may be any shape such as triangular, polygonal, closed conics (i.e. round or elliptical), or closed curve, but not limited to the circular shape as shown in FIG. 2A. The recess 121 is preferably rounded when the recess 121 is triangular or polygonal to prevent stress concentration at corners thereof, potentially further improving the product reliability of electronic apparatuses such as packages.

The recess 121 increases the adhesion area between an active device base and an active device such as a logic, memory, optronic, or other semiconductor device attached to the predetermined attachment area 110. More specifically, the recess 121 increases the adhesion area between the active device base and a glue layer adhering the active device to the predetermined attachment area 110 to improve adhesion therebetween. Thus, the interface between the glue layer and predetermined attachment area 110 may potentially be more resistant to thermal stress or other stress, thereby improving the product reliability of the electronic apparatus such as a package utilizing the active device base to pass the most critical reliability test standardized by JEDEC.

The shape and size of the predetermined attachment area 110 depends on the active device (not shown) predetermined for attachment thereto. When the active device is rectangular, the predetermined attachment area 110 is approximately rectangular. When the recess 121 is substantially at one of the corners of the rectangular predetermined attachment area 110, one of the corners of the active device attaching to the predetermined attachment area 110 is suspended over the recess 121, resulting in stress concentration during exertion of thermal stress thereon, thereby offsetting the product reliability improvement provided by the invention. The recess 121 may be anywhere in the predetermined attachment area 110, but substantially not at corners of the predetermined attachment area 110 when the predetermined attachment area 110 is rectangular.

In FIG. 2B, when a width of the recess 121 is less than 0.5 mm, the recess 121 may not be completely filled by the glue layer adhering the active device to the predetermined attachment area 110, thus, gas voids (not shown) may be formed therein. The voids may cause a “popcorn” effect delaminating the active device and predetermined attachment area 110. Further, a depth of the recess 121 is preferably between one fourth and one half of a thickness of the plate 100. When the depth of the recess 121 is greater than half of the thickness of the plate 100, the potential for improved product reliability is limited as the recess 121 thickens, but the use of the glue layer and possibility of formation of voids in the glue layer are increased. When the depth of the recess 121 is greater than half the thickness of the plate 100, only minimal potential improvement of product reliability may be observed.

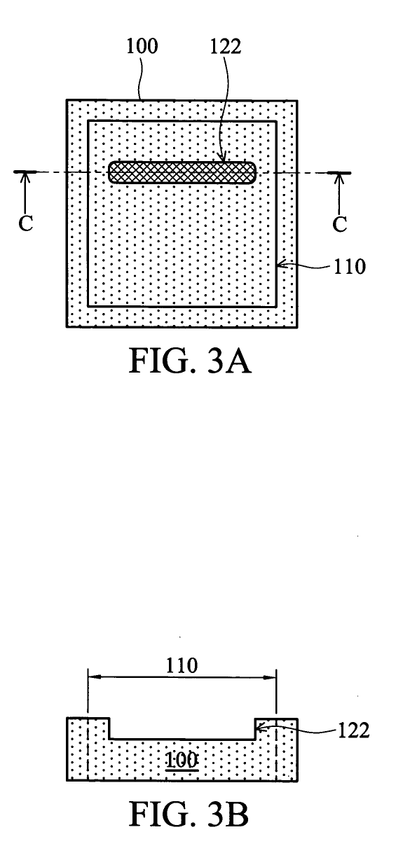

Next, variations to the recess 121 are described. Note that the variations shown in FIGS. 3A, 3B, 4, and 5 are exemplary, and not intended to limit the scope of the invention. Those skilled in the art will recognize the possibility of using various variations to achieve the aforementioned recess 121.

FIG. 3A is a top view of an embodiment of an active device base, and FIG. 3B is a cross-section along line CC in FIG. 3A, wherein a trench 122, substantially not penetrating the plate 100, replaces the recess 121 of FIG. 2A. The trench 122 has larger area, and thus, further increases the contact area between the glue layer and the active device base of the invention. The trench 122 is preferably rounded to potentially improve product reliability due to the invention.

When only one recess 121 or trench 122 is arranged, the location thereof is preferably beyond the center of the predetermined attachment area, further increasing potential reliability improvements.

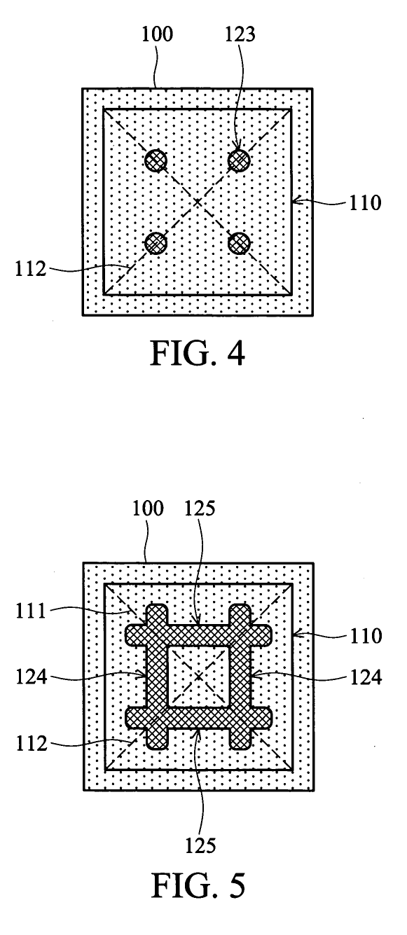

In FIG. 4, the recess 121 can be replaced by a plurality of individual sub-recesses 123. The individual sub-recesses 123 are preferably approximately symmetrically arranged in the predetermined attachment area 110 using the geometric center of the predetermined attachment area 110 as a reference point. For example, when the predetermined attachment area 110 is approximately rectangular, the intersection of diagonals 111 and 112 indicate the geometric center of the predetermined attachment area 110. Thus, potentially improved product reliability stays even in the predetermined attachment area 110, which is better than that resulting from random arrangement of the sub-recesses 123 in the predetermined attachment area 110. The sub-recesses 123 may be any geometric shape such as triangular, polygonal, closed conics (i.e. round or elliptical), or closed curve, but are not limited to round as shown in FIG. 4. The sub-recesses 123 are preferably rounded when the sub-recesses 123 are triangular or polygonal to prevent stress concentration at corners thereof to further improve the product reliability of an electronic apparatus such as a package utilizing the active device base of the invention.

Further, when the predetermined attachment area 110 is approximately rectangular and the active device base comprises four or more sub-recesses 123, four are preferably substantially at one-fourth and three-fourths of the diagonals 111 and 112 of the predetermined attachment area 110.

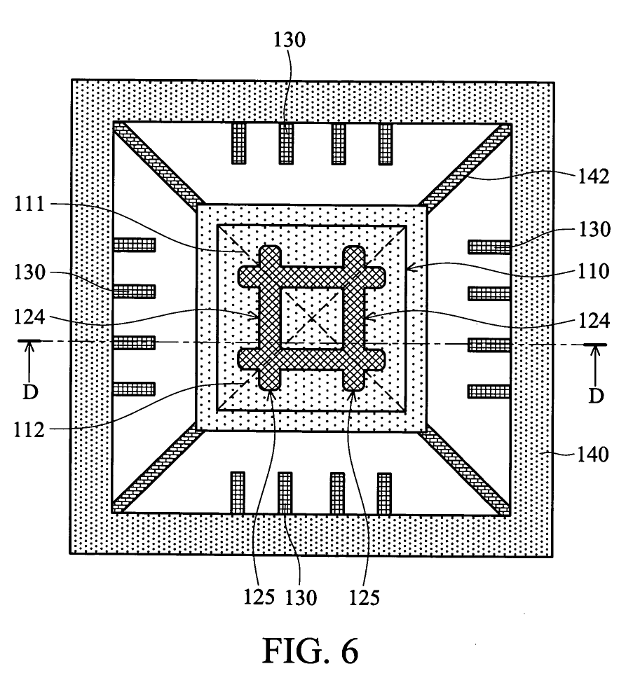

In FIG. 5, a plurality of intersecting trenches 124 and 125 can replace the recess 121. The trenches 124 and 125 are preferably approximately symmetrically arranged in the predetermined attachment area 110 using the geometric center of the predetermined attachment area 110 as a reference point. Similarly, the potentially improved product reliability stays even in the predetermined attachment area 110, which is better than that resulting from random arrangement of the trenches 124 and 125 in the predetermined attachment area 110. The trenches 124 and 125 are preferably rounded to further potentially improve product reliability.

Further, when the predetermined attachment area 110 is approximately rectangular and the active device base comprises respectively at least two trenches 124 and 125 arranged in a cross-hatch pattern, intersections of the cross-hatch pattern are preferably at one-fourth and three-fourths of the diagonals 111 and 112 of the predetermined attachment area 110.

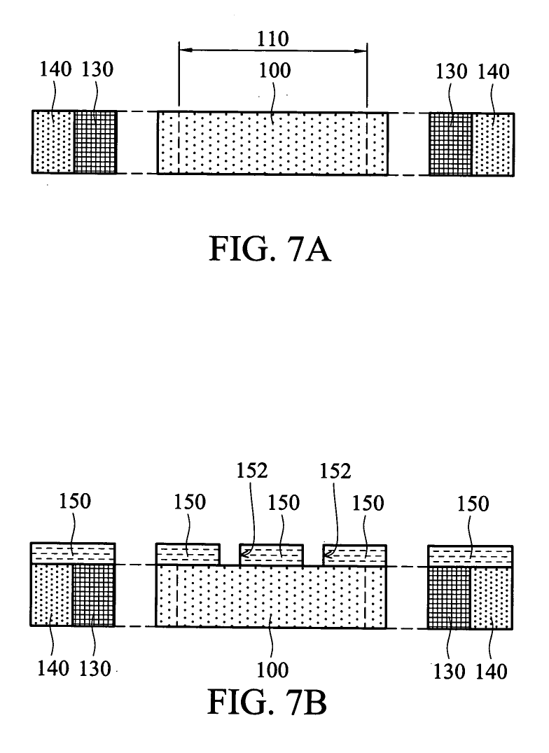

FIG. 6 is a top view of a leadframe of a second embodiment of the invention.

In this embodiment, the leadframe utilizes the active device base shown in FIG. 5. The active device base, however, can be replaced by that shown in FIGS. 2A, 3A, 4, or other compatible active device base.

In FIG. 6, the leadframe of the invention comprises the active device base of the invention, a plurality of terminals 130, and a peripheral boundary 140. Details regarding the plate 100, predetermined attachment area 110, diagonals 111 and 112, and trenches 124 and 125 are the same as those described for FIGS. 2A, 2B, and 5, and thus, are omitted in the following. The terminals 130 are disposed beyond the plate 100. The peripheral boundary 140 surrounds the terminals 130 and the plate 100, and is connected to the respective plate 100 and the terminals 130. The peripheral boundary 140 and plate 100 are connected by supporting bars 142.

When an active device, such as a logic, memory, optronic, or other semiconductor device, attaches to the predetermined attachment area 110 using a glue layer (not shown) therebetween, the trenches 124 and 125 as recesses in the leadframe utilizing the active device base of the invention increases adhesion area between the active device base and glue layer to increase adhesion therebetween, thereby improving resistance against thermal stress or other stress exerted thereon. Thus, an electronic apparatus such as a package utilizing an embodiment of the leadframe can pass the most critical reliability test standardized by JEDEC.

A fabrication method of the leadframe of the invention is described subsequently.

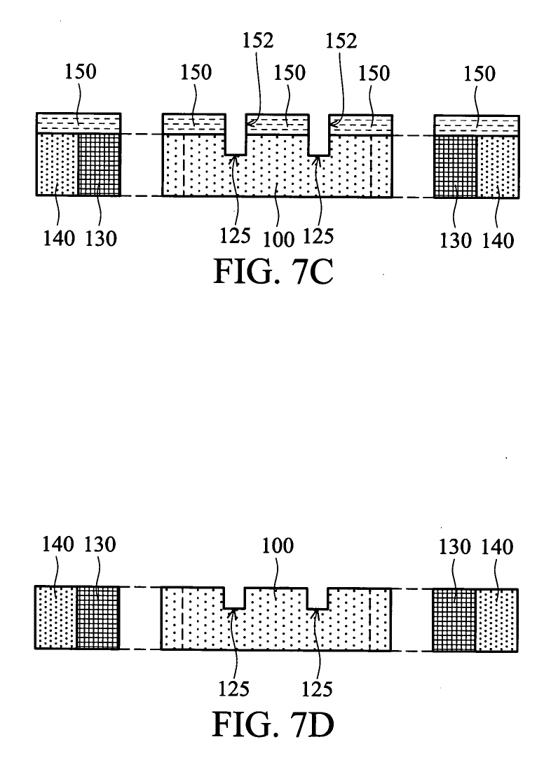

FIGS. 7A through 7D are cross-sections of a fabrication method of a leadframe of a third embodiment of the invention.

Note that the steps shown in FIGS. 7A through 7D are exemplary, and not intended to limit the scope of the invention. Those skilled in the art will recognize the possibility of using various methods to achieve a leadframe utilizing the active device base shown in FIGS. 2A, 3A, 4, or other compatible active device base.

In FIG. 7A, first, a semi-finished leadframe, comprising a plate 100, a plurality of terminals 130, and a peripheral boundary 140 is provided. The terminals 130 are beyond the plate 100. The peripheral boundary 140 surrounds the terminals 130 and the plate 100, and is connected to the respective terminals 130 and plate 100. Connections between the peripheral boundary 140 and plate 100 cannot be shown by FIG. 7A due to limitations of the cross-sectional view, but can be inferred by the supporting bars 142 therebetween in FIG. 6. Further, the plate 100 comprises a predetermined attachment area 100 for an active device on a surface.

Next, in FIG. 7B, a patterned mask layer 150 is formed overlying the plate 100. The patterned mask layer 150 comprises openings 150 exposing parts of the plate 100. The exposed plate 100 is where the recess is subsequently formed. The patterned mask layer 150 preferably covers other parts of the leadframe such as the terminals 130 and periphery area 140 to protect the parts during etching.

In FIG. 7C, the exposed plate 100 is etched to form a recess, which substantially does not penetrate the plate 100. In this embodiment, the recess comprises the trenches 124 and 125 shown in FIG. 6. The trenches 124 cannot be shown in FIG. 7C due to the limitations of the cross-sectional view. Depths of the trenches 124 and 125 can be controlled by controlling the etching time.

Finally, the patterned mask layer 150 is removed to achieve the leadframe as shown in FIG. 7D, which is a cross-section along line DD in FIG. 6.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. An active device base, comprising:
a plate;
a predetermined attachment area for an active device on a surface of the plate; and
a recess, substantially not through the plate, in the predetermined attachment area.

2. The base as claimed in claim 1, wherein the predetermined attachment area is substantially rectangular, and the recess is substantially not at any of the four corners of the predetermined attachment area.

3. The base as claimed in claim 1, wherein the recess comprises a plurality of individual sub-recesses symmetrically arranged in the predetermined attachment area using the geometric center thereof as a reference point.

4. The base as claimed in claim 1, wherein the recess comprises a plurality of trenches symmetrically arranged in the predetermined attachment area using the geometric center thereof as a reference point.

5. The base as claimed in claim 1, wherein a depth of the recess is between one fourth and half of a thickness of the plate.

6. The base as claimed in claim 1, wherein the recess is as wide as 0.5 mm or greater.

7. The base as claimed in claim 1, wherein the predetermined attachment area is substantially rectangular, and the recess comprises four individual sub-recesses respectively at approximately one fourth and three fourths of the diagonals of the predetermined attachment area.

8. The base as claimed in claim 1, wherein the predetermined attachment area is substantially rectangular, the recess comprises four trenches substantially arranged in a cross-hatch pattern, wherein intersections of the trenches are respectively at approximately one fourth and three fourths of the diagonals of the predetermined attachment area.

9. A leadframe, comprising:
a plate;
a predetermined attachment area for an active device on a surface of the plate;
a recess, substantially not through the plate, in the predetermined attachment area;
a plurality of terminals beyond the plate; and
a peripheral boundary sandwiching the terminals with the plate, connected to the respective plate and the terminals.

10. The leadframe as claimed in claim 9, wherein the predetermined attachment area is substantially rectangular, and the recess is substantially not at any of the four corners of the predetermined attachment area.

11. The leadframe as claimed in claim 9, wherein the recess comprises a plurality of individual sub-recesses symmetrically arranged in the predetermined attachment area using geometric center thereof as a reference point.

12. The leadframe as claimed in claim 9, wherein the recess comprises a plurality of trenches symmetrically arranged in the predetermined attachment area using geometric center thereof as a reference point.

13. The leadframe as claimed in claim 9, wherein a depth of the recess is between one fourth and half of a thickness of the plate.

14. The leadframe as claimed in claim 9, wherein the recess is as wide as 0.5 mm or greater.

15. The leadframe as claimed in claim 9, wherein the predetermined attachment area is substantially rectangular, and recess comprises four individual sub-recesses respectively at approximately one fourth and three fourths of the diagonals of the predetermined attachment area.

16. The leadframe as claimed in claim 9, wherein the predetermined attachment area is substantially rectangular, the recess comprises four trenches substantially arranged in a cross-hatch pattern, wherein intersections of the trenches are respectively at approximately one fourth and three fourths of the diagonals of the predetermined attachment area.

17. A fabrication method of a leadframe, comprising:
providing a semi-finished leadframe, comprising a plate, a plurality of terminals beyond the plate, and a peripheral boundary surrounding the terminals and the plate, connected to the respective plate and the terminals;
forming a patterned mask layer overlying the plate, exposing parts of the plate;
etching the exposed plate but not substantially through the plate, resulting in formation of a recess; and
removing the patterned mask layer.

18. The method as claimed in claim 17, wherein the predetermined attachment area is substantially rectangular, and the recess is substantially not at any of the four corners of the predetermined attachment area.

19. The method as claimed in claim 17, wherein the recess comprises a plurality of individual sub-recesses symmetrically arranged in the predetermined attachment area using geometric center thereof as a reference point.

20. The method as claimed in claim 17, wherein the recess comprises a plurality of trenches symmetrically arranged in the predetermined attachment area using geometric center thereof as a reference point.

21. The method as claimed in claim 17, wherein a depth of the recess is between one fourth and one half of a thickness of the plate.

22. The method as claimed in claim 17, wherein the recess is as wide as 0.5 mm or greater.

23. The method as claimed in claim 17, wherein the predetermined attachment area is substantially rectangular, and the recess comprises four individual sub-recesses respectively disposed at approximately one fourth and three fourths of the diagonals of the predetermined attachment area.

24. The method as claimed in claim 17, wherein the predetermined attachment area is substantially rectangular, the recess comprises four trenches substantially arranged in a cross-hatch pattern, wherein intersections of the trenches are respectively at approximately one fourth and three fourths of the diagonals of the predetermined attachment area.
